(19) United States
(12) Patent Application Publication
(10) Pub. No.: US 2026/0354108 A1
(43) Pub. Date: Nov. 5, 2026

(54) Handler and Method for Handling Electronic Components During Separation of Assembled Electronic Components

(71) Applicant: Besi Netherlands B.V., Duiven (NL)

(72) Inventor: Sebastianus Hubertus Maria Kersjes, Lent (NL)

(21) Appl. No.: 19/478,520

(22) PCT Filed: Apr. 23, 2024
(86) PCT No.: PCT/NL2024/050211

§ 371 Date: Oct. 24, 2025

(30) Foreign Application Priority Data
Apr. 26, 2023 (NL) 2034694

(51) Int. Cl. H10P 72/70; H10P 58/00

(52) U.S. Cl. CPC H10P 72/7422; H10P 58/00; H10P 72/7416

(57) ABSTRACT

The invention relates to a handler for handling electronic components during separation of assembled electronic components, including a contact surface with plural separated chambers, which separated chambers are opened to the contact side and are provided with sidewalls, wherein at least one central chamber is at least partially surrounded by at least one circumferential chamber and wherein the at least one central chamber and the at least one circumferential chamber are provided with different gas passage openings. The invention also relates to a method for handling electronic components during separation of assembled electronic components, with such a handler.

### CROSS-REFERENCE TO RELATED APPLICATIONS

This application is the United States national phase of International Patent Application No. PCT/NL2024/050211 filed Apr. 23, 2024, and claims priority to The Netherlands Patent Application No. 2034694 filed Apr. 26, 2023, the disclosures of which are hereby incorporated by reference in their entireties.

### BACKGROUND OF THE INVENTION

### Field of the Invention

The invention relates to a handler for handling electronic components during separation of assembled electronic components, comprising a contact surface with plural separated chambers, in which separated chambers are opened to the contact side and are provided with sidewalls. The invention also relates to a method for handling electronic components during separation of assembled electronic components, with such a handler.

### Description of Related Art

In the final stages of electronic components fabrication, the assembled configuration fabricated electronic components may be separated (singulated, diced) to obtain individual products. An example of such fabrication is the production of semiconductors (ICs). The semiconductor package substrate comprising the plurality of semiconductor packages is divided into individual semiconductor packages using package singulation. Singulation may take place through machining a substrate interconnecting the individual products e.g. with a rotating saw blade, wherein the assembled electronic components may be formed by a wafer, a lead frame, or a board. As part of the machining operation, chips and/or other debris will be produced and often also a liquid coolant is used. This may result in undesired pollution of sensitive parts of the electronic components during the separation process. A commonly used solution is to cover the sensitive parts of the electronic components before the separation process starts with a detachable tape which will stick to the sensitive parts of the electronic components during the separation process. After the separation is effected the tape is detached from the separated electronic components. The attachment and detachment of the tape are labour intensive processes also because the electronic components involved in general are relatively small, typically falling within an order of magnitude of several millimetres, for instance between 3×3 mm and 20×20 mm, and there is a trend towards even smaller electronic components. There is thus a demand for an alternative solution to keep sensitive parts of the electronic components free of pollution during the separation process that does not have the limitations of the tape covering prior art solution.

The problem of the prior art solutions in keeping sensitive parts of the electronic components free of undesired pollution during machining of moulded electronic component is time consuming and not always provides the required results.

### SUMMARY OF THE INVENTION

Hence, the goal of the present invention is to overcome these disadvantages and provide a solution for keeping sensitive parts of the electronic components free of undesired pollution during machining of moulded electronic component that enables easier and/or cheaper processing and/or better results.

To realise this goal the present invention provides a handler for handling electronic components during separation of assembled electronic components, comprising: a contact surface with plural separated chambers, which separated chambers are opened to the contact side and are provided with sidewalls, wherein at least one central chamber is at least partially surrounded by at least one circumferential chamber and wherein the at least one central chamber and the at least one circumferential chamber are provided with different gas passage openings. The central chamber may be surrounded by a single, e.g. circular/coaxial, circumferential chamber but the central chamber may also only partially be surrounded by one or more circumferential chambers. The shape of the chambers maybe of any shapes, for instance, circle, ellipse, square, rectangular, hexagonal, and the like. The separation of assembled electronic components may be realised in a singulation process, like for instance by a machining process as for instance sawing or cutting, or alternatively by an etching process like for instance plasma etching. The singulation is realized from the side of the electronic components that are faced away from the handler (so the opposite side of the electronic components than the side that is contacted by the handler). Typically during singulation, there is a substantial amount of chips, debris, deposition or other type of pollution that might be generated. Such pollution might contaminate the semiconductors and more specific also the sensitive parts of the electronic components. The present invention now provides the opportunity to vary the gas pressure level between a central chamber and the corresponding at least one circumferential chamber such that the pressure level in the at least one circumferential chamber is lower than in the corresponding central chamber. The advantage of such pressure level difference is that the central chambers may cover—and thus protect—the sensitive parts of the electronic components against pollution. An even further protection against pollution of the sensitive parts of electronic components may be provided in that any pollution in the vicinity of a central chamber will have preference to move towards a circumferential chamber as there the gas pressure level is lower than in the central chamber. Suction of pollution into the (normally underpressurized) chambers must preferably be limited as far as possible, but complete avoidance of pollution entering a chamber anyhow is difficult (in practise impossible) to realise. As far as any pollution enters the circumferential chambers this is not seriously negatively effecting the quality of the electronic components as long as the pollution enters one or more of the circumferential chambers alone (and not the central chamber(s)) as the circumferential chambers are not covering the sensitive parts of the electronic components; any pollution there is less harmful. Most important is to keep the central chamber free of pollution as the central chamber covers the sensitive part of an electronic components. This effect may even further supported when in the central chamber(s) a pressure level is realised that is higher than the pressure level of the ambient gas (air). The handler according to the present invention enables not only to cover the sensitive parts of electronic components but also to create pressure level differences that are further supportive in keeping the sensitive parts of the electronic components free of pollution. Therefore the new handler may provide a double protective effect for the sensitive parts which thus provides a high level of protection, and thus a high level of quality. A further advantage of the handler according to the present invention is that the handler is easy to position and make the time consuming individual covering, and—after the singulation has taken place—removing the covering of the sensitive parts of the electronic components superfluous. The present handler enables thus not only to realise a high quality covering but is also simple and time saving in use compared to the prior art covering technique.

During the singulation process material from the electronic components may be removed outside the area where the central chamber(s) cover(s) the sensitive part(s). The material may thus be removed at any locations outside the area covers by the central chamber(s). This also included singulation locations that are (partially) covered by the circumferential chamber(s) in which situation the circumferential chamber(s) may be used for active removal of debris. The pressure level regulation in central and circumferential chambers may be regulated automatically but also any (additional) manual regulation is possible. The pressure level in the central chamber(s) during the processing is preferably lower that the ambient gas (air) pressure level. This is supportive in a solid engagement of the electronic components by the handler. The handler may also be provided with one or more mechanical clamps to grab the electronic components mechanically.

In an embodiment the distant sides of the sidewalls of the chambers lie in a single surface. Advantageously, this will provide the opportunity to handle electronic components/dies with a uniform height. Alternatively, the distant sides of the sidewalls of the chambers may lie in various surfaces. The differences in height enable the handling of electronic component packages that include height differences.

The sidewalls may comprise at least a flexible material, or a non-flexible material, or a combination thereof. The advantage of using sidewall that are more or less flexible is that they may adapt to unforeseen circumstances, while the advantage of using non-flexible (stiff) sidewalls is that they provide certainty regarding the exact positions of the sidewalls. In another embodiment, the handler may comprise a stable base from which the sidewalls are protruding. The gas passage openings of the central chamber(s) and the circumferential chamber(s) may pass through the stable base. The stable base provides that the position of the handler is very manageable. At least a part of the stable base may also be covered by a non-flexible material, flexible material, or a combination thereof. For instance the material flexible protruding walls are made of a silicon or rubber material.

To control the movement of the handler, the handler may comprise a manipulator for controlling movements of the contact surface with the plural separated chambers. For instance, the manipulator, such as at least a robot arm or multiple robot arms manipulator, may be automatically controlled by a programmable control unit. This may enhance the accuracy and speed of a large scale singulation production process.

The present invention also provides the handler which may comprise at least two independent controllable gas pressure level regulators connecting to the gas passage openings of the at least one central chamber and the at least one circumferential chamber. It is possible that both central and circumferential chamber pressure levels are decreased to below the ambient pressure level but alternatively at least the central chamber gas pressure level may be higher than the ambient gas (air) pressure level to minimise the risk that pollution enters the central chamber. The gas pressure level regulators of each of the chamber types are preferably independent controllable in terms of regulating pressure levels and/or type of gasses. Non-limiting examples of gas pressure regulators are pumps, extractors, ventings, underpressure or overpressure central gas pipe systems. The gas pressure level regulators may be manually or automatically controlled. The regulator may for instance being controlled by a mass flow controller with integrated pressure level regulator device or an electronic pressure level regulator. In case of plural central and circumferential chambers being combined in a single manipulator, as will normally be the situation, the pressure level regulation preferably may take place on an individual chamber level. This enables for instance to avoid substantial pressure level loss in case one or more positions on an electronic component assembly are open and/or when one or more chambers due to other reasons are not sealing properly on the electronic component assembly. The control unit may also control other parameters used in the singulation process of the present invention. For example, time, movements, safety control, maintenance, data monitoring, positions (of for instance handler, substrate, individual electronic components, individual chambers, etc. Advantageously, the control unit may assist the user by having the capacity to record, store, and recall a particular pressurizing procedure, such as certain settings for various gas types, amount of pressure levels, and/or chamber openings. The control unit may also regulate the singulation process.

In a further embodiment, the handler comprises plural chamber groups of at least one central chamber surrounded by at least one circumferential chamber wherein the central chambers and the circumferential chambers are provided with different gas passage openings. Each chamber comprises at least one gas passage opening. The gas passage openings may deliver different pressure levels to each chamber. In this way, in each chamber a well-controlled pressure level can be achieved.

The present invention also provides a method for handling electronic components during separation of assembled electronic components, with a handler for handling electronic components according to the present invention, comprising the method steps of: A) contacting an electronic components assembly with the contact side of the handler whereby at least one assembly part sensitive to pollution is covered by a central chamber, and at least on part surrounding that is less sensitive to pollution than the sensitive to pollution part is covered by at least one circumferential chamber; B) bringing the at least one circumferential chamber on a lower pressure level than the ambient pressure level, whereby the pressure level in the at least one central chamber is higher than the pressure level in the at least one circumferential chamber; C) separating the assembled electronic components while maintaining a higher pressure level in the at least one central chamber than in the at least one circumferential chamber; and D) increasing the pressure level in the at least one circumferential chamber and releasing the separated electronic components. In a specific embodiment of this method during method step B) both the at least one central chamber and the at least one circumferential chamber are brought on a lower pressure level than the ambient pressure level, and during method step D) the pressure level in both the at least one central chamber and the at least one circumferential chamber is increased. The advantages of this method using the handler assembly according to the present invention are already specified above and here incorporated in relation to the method for handling the electrical components for singulation according to the present invention. The method in the present invention will lead to an enhanced effectivity and efficiency in preventing contamination of sensitive parts of electronic components during singulation (sawing or cutting for example). The present method is beneficial as no additional cleaning method step is required to remove contamination and/or to remove shielding elements (like tapes) from the singulated electronic components. This may lead to a shorter singulation cycle time. In a further advantageous application of the method, the electronic component part sensitive to pollution may for instance be embodied as a sensor, detector, optical window, lens, heat exchanging surface, microprocessor, magnetic element, radio frequency sensitive element or microelectromechanical system (MEMs). The part of an electronic component that is sensitive to pollution is not only protected from pollution by the present invention, but is also shielded from any other contact that could negatively influence its quality (e.g. wear, abrasion, oxidation or the like). This further contributes to the quality of the separated electronic components. Besides, the time and performance in every singulation cycle may also improve.

In a specific application of the method according to the invention a pressure level difference between one or more central chambers and one or more circumferential chambers during process step C) is at least 5 mbar. The pressure level in the at least one central chamber may be regulated within a range of [5-1024] mbar and in the pressure level in the at least one circumferential chamber may be regulated within a range of [5-500] mbar. This pressure level difference minimises the risk of pollution entering the at least one central chamber, as the pollution will have a preference to enter the at least one circumferential chamber first. It is also preferred that a singulated electronic component is still attached to the handler during and afterwards the singulation took place. Therefor it is preferred that if the central chamber is not at a pressure level below ambient pressure level during the singulation process (or during the initial phase of the singulation process) the pressure level is lowered to a level below the ambient pressure level before the singulation is final so that the handler still seizes the singulated electronic components.

In another specific application of the method according to the invention, the pressure level in the chambers before process step C) may be adapted to limit distortion (warpage) of the electronic components assembly. This may be performed automatically by using a control unit that receives input regarding the flatness, or the lack thereof, of the electronic components assembly. Thus, an improved accuracy of the singulation process may be achieved.

### BRIEF DESCRIPTION OF THE DRAWINGS

The terms FIG., FIGS., Figure, and Figures are used interchangeably in the specification to refer to the corresponding figures in the drawings.

The invention will be further elucidated with reference to the non-limitative exemplary embodiments shown in the following figures. Corresponding elements are designated in the figures with corresponding reference numerals. Herein shows:

FIG. 1 a schematic perspective cross-section view on a handler according to the present invention holding an electronic component;

FIG. 2A a schematic cross-cut view on an electronic component assembly before singulation;

FIGS. 2B and 2C schematic cross-cut views on a handler according to the present invention holding an electronic component assembly during subsequent method steps of the present invention;

FIG. 2D a schematic cross-cut view on an electronic component assembly that is singulated according the step elucidated in FIGS. 2B and 2C;

FIG. 3 a perspective view on an embodiment of a handler according to the present invention comprising a plurality of central chambers; and

FIGS. 4A-4C various schematic top views on alternative embodiments of central chambers and circumferential chambers to be used in a handler according to the present invention.

### DESCRIPTION OF THE INVENTION

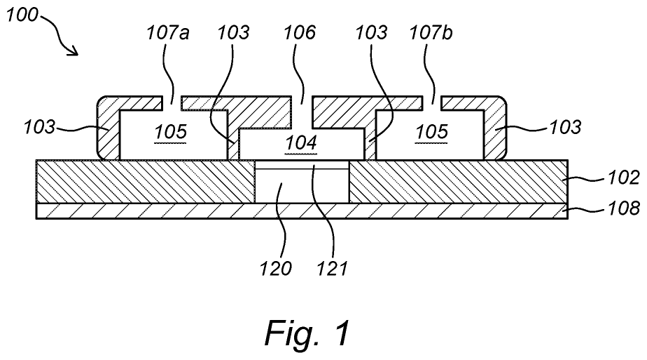

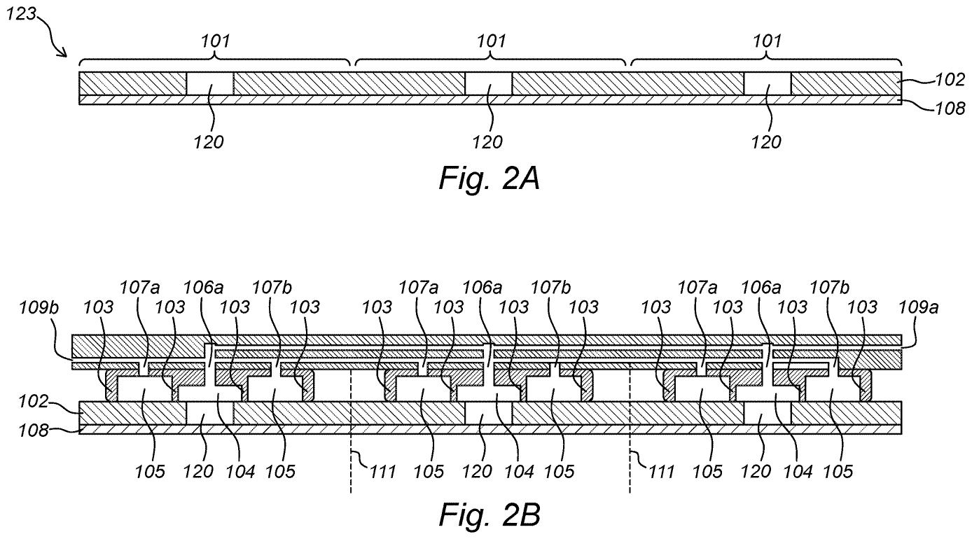

FIG. 1 shows a schematic cross-section view on a handler (100) holding an moulded electronic component package (101) that is being formed by a substrate (108) carrying an electronic component (120) that is encapsulated by an encapsulating material (102). The electronic component (120) has a surface part (121) that is sensitive to pollution. The handler (100) comprises plural chambers (104, 105); a central chamber (104) and two circumferential chambers (105). The chambers (104, 105) comprise sidewalls (103), which separate the chambers (104, 105) from each other. The central chamber (104) further comprises a gas passage opening (106) to enable pressure level adjustment within the central chamber (104). Each of the circumferential chambers (105) also comprises a gas passage opening (107a, 107b) also to enable pressure level adjustment within the circumferential chambers (105). The gas passage openings (106, 170a, 170b) are connected to pressure level regulators (not shown) for independently adjust the pressure level in the chambers (104, 105). The pressure level in each of the chambers (104, 105) may vary independently from each other. Due to a close contact of the handler (100) with a contact surface (102) of the moulded electronic component package (101), preferably a contact that is close to airtight, the pressure level in the chambers (104, 105) may differ from the ambient pressure level. The pressure level of the central chamber (104) must be higher than the (under)pressure level of the circumferential chamber (105), preferably at least 5 mbar higher. It is also possible that the pressure levels in the chambers (104, 105) are adjusted or adapted to limit the warpage of the electronic component (101). The pressure level difference between the central chamber (104) and the circumferential chamber (105) will keep the central chamber (104) free of pollution from separation process as the pollution has a preference to enter the circumferential chambers (105) such that the surface part (121) that is sensitive to pollution of the electronic component (101) remains substantially free from pollution.
FIG. 2A shows an assembly of multiple moulded electronic components (101) with a common substrate (108) and connected encapsulating material (102) wherein electronic components (120) are embedded. FIG. 2A shows the uncut assembly of the multiple moulded electronic components (101).

FIGS. 2B-2C show schematic cross-cut views of a handler according to the present invention holding an electronic component assembly (123) during subsequent method steps of the present invention. In FIG. 2B gas supply/discharge feeds (109a, 109b) of the handler (100) connect to gas passage openings (106a, 106b, 106c, 107a, 107b, 107c, 107d). The gas supply/discharge feeds (109a, 109b) enable independent pressure level adjustment or regulation in each chamber (104, 105). The gas supply/discharge feed (109a) to the central chambers (104) via gas passage openings (106a, 106b, 106c) enables pressure level adjustment to keep especially the central chambers (104) free of pollution.

The other gas supply/discharge feed (109b) connects to the circumferential chambers (105) via gas passage openings (107a, 107b, 107c, 107d) and enables pressure level adjustment in the circumferential chambers (105), also not with the intention to attract pollution but as far as any pollution may approach the central chambers (104) to attack such pollution better in the circumferential chambers (105) before it would enter one of the central chambers (104). An underpressure level in at least the circumferential chambers (105), but optionally also in the central chambers (104) and acting onto the contact surface (102) of the electronic component assembly (123) will also affect the attachment of assembly (123) to the handler (100). The handler (100) comprises a stable base (110) from which sidewalls (103) protrude separating the chambers (104, 105). The stable base (110) of the handler (100) holds the gas passage openings (106a, 106b, 106c, 107a, 107b, 107c, 107d) and the gas supply/discharge feeds (109a, 109b), which connect to (not shown) gas feed/discharge means. The sidewalls (103) will normally abut against the contact surface (102) of the electronic component assembly (123).

FIG. 2C shows the electronic component assembly (123) from FIG. 2B after singulation divided in individualised moulded electronic components (101). The singulation process by a saw blade (112) resulted in cutting lines (111) that end outside both the central chambers (104) and the circumferential chambers (105). The pollution such as chips/debris from e.g. machining or lasering the cutting lines (111) will partially be collected in and discharged through the circumferential chambers (105). Due to the pressure level in the circumferential chambers (105) that is lower than the pressure level in to the central chambers (104), the pollution will not (or only on a very limited scale) enter the central chambers (104). After singulation, the handler(100) will be detached from the contact surfaces (102) by increasing the pressure level in the chambers (103, 104), normally at least until the ambient pressure level. This will result in a plurality of individualised moulded electronic components (101)as shown on FIG. 2D.

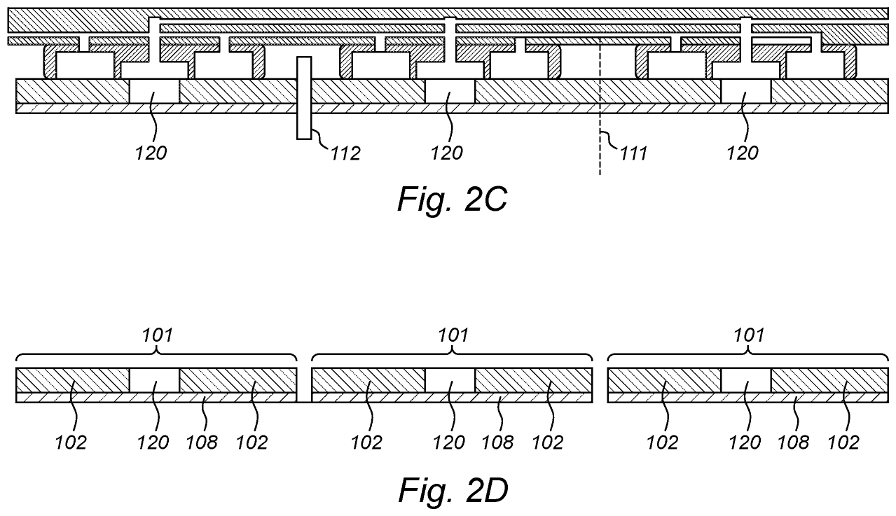

FIG. 3 shows a perspective view on a contact surface of another embodiment of a handler (200) according to the invention comprising a plurality of central chambers (201).

Here the multiple central chambers (201) are surrounded by one single circumferential chamber (202). Each of the central chambers (201) is provided with a gas passage opening (203) and also in the circumferential chamber (202) gas passage openings (204) are shown.

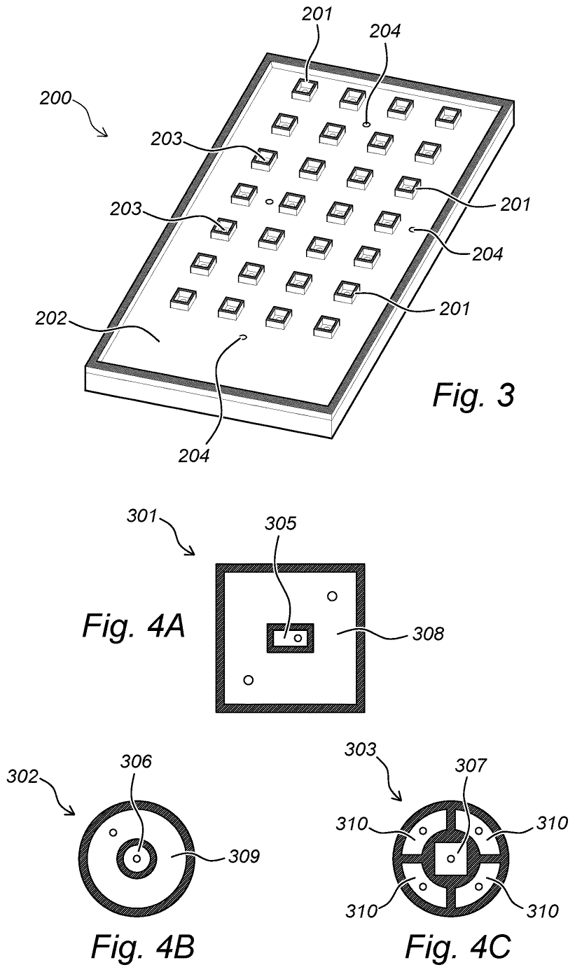

FIGS. 4A-4C show schematic top-views on alternative embodiments of compositions (301, 302, 303) of central chambers (305, 306, 307) and circumferential chambers (308, 309, 310) to be used in a handler according to the present invention.

FIG. 4A shows a square central chamber (305) completely surrounded by a square circumferential chamber (308).

FIG. 4B shows a circular central chamber (306) completely surrounded by a circular circumferential chamber (309).

FIG. 4C shows a square central chamber (307) around which four lunar-shaped circumferential chambers (310) lei without completely surrounding the central chamber 307).

The above-described inventive concepts are illustrated by several illustrative embodiments. It is conceivable that individual inventive concepts may be applied without, in so doing, also applying other details of the described example.

The verb “comprise” and conjugations thereof used in this patent publication are understood to mean not only “comprise”, but are also understood to mean the phrases “contain”, “substantially consist of”, “formed by”, and conjugations thereof.

1. A handler for handling electronic components during separation of assembled electronic components, comprising a contact surface with plural separated chambers, which separated chambers are opened to the contact side and are provided with sidewalls, wherein at least one central chamber is at least partially surrounded by at least one circumferential chamber and wherein the at least one central chamber and the at least one circumferential chamber are provided with different gas passage openings.

2. The handler according to claim 1, wherein distant sides of the sidewalls of the chambers lie in a single surface.

3. The handler according to claim 1, wherein the distant sides of the sidewalls of the chambers lie in a-various surfaces.

4. The handler according to claim 1, wherein the sidewalls comprise at least a flexible material, or a non-flexible material, or a combination thereof.

5. The handler according to claim 1, wherein the handler comprises a stable base from which the sidewalls are protruding.

6. The bandler according to claim 1, wherein the handler includes a manipulator for controlled movement of the contact surface with plural separated chambers.

7. The handler according to claim 1, wherein the handler comprises at least two independent controllable gas pressure level regulators connecting to the gas passage openings of the at least one central chamber and the at least one circumferential chamber.

8. The handler according to claim 1, wherein the handler comprises plural chamber groups of at least one central chamber surrounded by at least one circumferential chamber wherein the central chambers and the circumferential chambers are provided with different gas passage openings.

9. A method for handling electronic components during separation of assembled electronic components, with a handler for handling electronic components according to claim 1, comprising the method steps:
A) contacting an electronic components assembly with the contact side of the handler whereby at least one assembly part sensitive to pollution is covered by a central chamber, and at least on part surrounding that is less sensitive to pollution than the sensitive to pollution part is covered by at least one circumferential chamber;
B) bringing at least one circumferential chamber on a lower pressure level than the ambient pressure level, whereby the pressure level in the at least one central chamber is higher than the pressure level in the at least one circumferential chamber;
C) separating the assembled electronic components while maintaining a higher pressure level in the at least one central chamber than in the at least one circumferential chamber; and
D) increasing the pressure level in the at least one circumferential chamber and releasing the separated electronic components.

10. The method according to claim 9, wherein during method step B) both the at least one central chamber and the at least one circumferential chamber are brought on a lower pressure level than the ambient pressure level, and that during method step D) the pressure level in both the at least one central chamber and the at least one circumferential chamber is increased.

11. The method according to claim 10, wherein the at least one assembly part sensitive to pollution is chosen from the group of sensors, detectors, optical windows, lenses, heat exchanging surfaces, microprocessors, magnetic, radio frequency, power management, microelectromechanical system (MEMs), and the like.

12. The method according to claim 9, thatwherein a pressure level difference between central and circumferential chambers during process step C) is at least 5 mbar.

13. The method according to claim 9, in during process step C) the pressure level in at least one central chamber is within the range of [5-1024] mbar and the pressure level in the at least one circumferential chamber is within the range of [5-500] mbar.

14. The method according to claim 9, wherein the pressure levels in the chambers before process step is adapted to limit distortion (warpage) of the electronic components assembly.
